(19) United States
(12) Patent Application Publication
(10) Pub. No.: US 2008/0258807 A1
(43) Pub. Date: Oct. 23, 2008

(54) Basic semiconductor electronic circuit with reduced sensitivity to process variations

(75) Inventors: Ignazio Martines, Tremestieri Etneo (IT); Michele La Placa, Cefalu (IT)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMicroelectronics S.r.I., Agrate Brianza (IT)

(21) Appl. No.: 11/455,896

(22) Filed: Jun. 19, 2006

(30) Foreign Application Priority Data
Jun. 20, 2005 (EP) 05425440.4

(51) Int. Cl. H03H 11/00

(52) U.S. Cl. 327/581

(57) ABSTRACT

A basic electronic circuit generates a magnitude. The circuit has certain structural characteristics and the magnitude undergoes variations in function of the structural characteristics of the circuit. The circuit comprises at least two circuit parts suitable for supplying respective fractions of the magnitude and the at least two circuit parts have different structural characteristics.

### BACKGROUND OF THE INVENTION

1. Field of the Invention

The present invention refers to a basic electronic semiconductor circuit with reduced sensitivity to process variations.

2. Description of the Related Art

In the field of electronic semiconductor apparatus and above all of memory circuits there is a growing demand to obtain basic circuits, such as reference current generators, reference voltage generators, delay chains, etc., as precise as possible, that is independent from the variations of the supply voltage, from the temperature variations and from the process parameters.

Currently, for example, the majority of the highest precision reference current generators are obtained by means of feedback circuits comprising a high gain amplifier. In this manner the output magnitude becomes a function of the passive network of the “ratio” type, with a transfer function that is not very sensitive to the process variations and thus acceptable in the majority of applications.

The feedback circuits used in the above-mentioned reference current generators however absorb a high current for functioning; this can lead to turning them off in certain periods of time. Nevertheless said circuits take a certain period of time for turning on and thus cannot be used in those circuitries in which a precise current, ready in a very short time of the order of a few nanoseconds, is necessary.

It is also necessary for the delay chains to obtain a high response speed and therefore high constructive simplicity with low occupation of area on the chip.

Known reference current generators circuits are shown in FIGS. 1 and 1a.

The circuit of FIG. 1 is made by means of a circuit configuration with an NMOS transistor M1 with the source terminal connected to ground GND. A current I flows in the transistor M1 of the NMOS type and the transistor M1 is piloted by a precise voltage signal BG and for example in output from a bandgap circuit.

The circuit of FIG. 1a is made by means of a circuit configuration similar to the circuit of FIG. 1 but in which a resistance R1 is provided between the source terminal of the transistor M1 and the ground GND. A current I flows in the transistor M1 of the NMOS type and the transistor M1 is piloted by a precise voltage signal BG and for example in output from a bandgap circuit.

Said reference current generators are of the non-feedback type and they have a high turn-on speed. Nevertheless said reference current generators are stable, that is with limited variations, if we assume working ideally with a very stable process, that is with structural parameters or characteristics whose variations are small. In reality in the production of devices at industrial level the process parameters vary widely; this leads to a variation of the reference current generated by a significant percentage.

Considering the circuit of FIG. 1a, we have a dependence of the reference current on the parameters of the active element, that is on the parameters of the transistor M1, and on the parameters of the passive element, that is on the resistance R1, which are not correlated to each other. The variations of both or on only one of said elements can lead to a variation of the reference current of at least 15-20%. We have the current

$$I = K \frac{W}{L} {( Vgs - Vt )}^{2}$$

where Vgs is the voltage between the gate and source terminals, W is the width of the gate and L is the length of the gate of the transistor MOS M1,

$$K = μ \frac{Cox}{2}$$

where μ is the mobility, Cox is the capacitance of the oxide that depends on the thickness Tox, Vt is the threshold voltage that depends on the temperature and

$$R = Rs \frac{Ws}{Ls}$$

where Rs is the layer resistance and Ws and Ls are the width and the length of the semiconductor layer; it is not possible to have effect with project choices on the parameters μ, Vt and Rs.

### BRIEF SUMMARY OF THE INVENTION

One embodiment of the present invention provides a basic electronic semiconductor circuit with reduced sensitivity to process variations that overcomes the above-mentioned inconveniences.

One embodiment of the present invention is a basic electronic circuit suitable for generating a magnitude. The circuit has certain structural characteristics and the magnitude undergoes variations in function of the structural characteristics of the circuit. The circuit includes at least two circuit parts suitable for supplying respective fractions of said magnitude. The at least two circuit parts have different structural characteristics from each other.

### BRIEF DESCRIPTION OF THE SEVERAL VIEWS OF THE DRAWINGS

The characteristics and advantages of the present invention will appear evident from the following detailed description of its embodiments thereof, illustrated as non-limiting example in the enclosed drawings, in which:

FIG. 1 is a circuit diagram of a reference current generator in accordance with the known art;

FIG. 1a is another circuit diagram of a current generator in accordance with the known art;

FIG. 2 is a circuit diagram of a first basic electronic circuit in accordance with the present invention;

FIG. 3 is a circuit diagram of a basic electronic circuit in accordance with a construction variant of the circuit of FIG. 1;

FIG. 4 is a circuit diagram of a further basic circuit in accordance with the present invention.

### DETAILED DESCRIPTION OF THE INVENTION

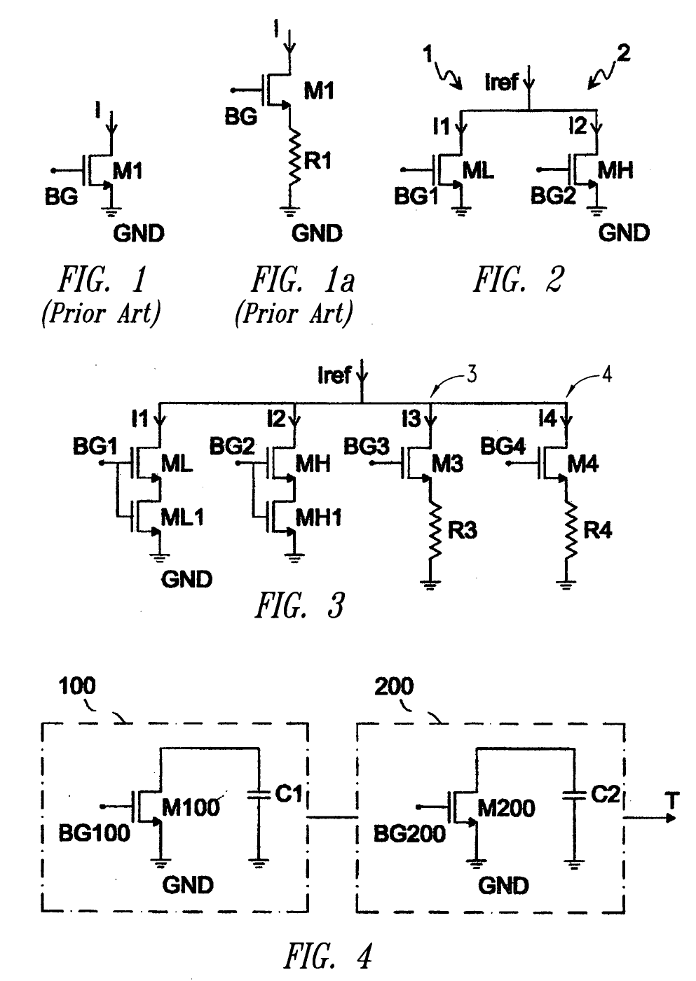

FIG. 2 shows a reference current generator Iref in accordance with one embodiment of the present invention. The generator comprises a circuit part 1 made up of a low voltage transistor ML and a circuit part or branch 2, arranged in parallel with the circuit part or branch 1, made up of a transistor for high voltages MH; at the gate terminals of the transistors ML and MH the bandgap voltages BG1 and BG2 are applied respectively and the source terminals are connected to ground GND. A current I1 flows in the circuit part 1 while a current I2 flows in the circuit part 2 such that I1+I2=Iref. Given that the threshold voltage Vtl of a low voltage transistor is not correlated by the threshold voltage Vth of a high voltage transistor, it can be said that approximately only for the transistor ML there is a variation of the current I1 in relation to the threshold voltage Vtl. In this case the variation of the reference current Iref in relation to the threshold voltage Vtl is lower than the variation that the current Iref would undergo if it was generated by the circuit of FIG. 1 in which the transistor M1 is a transistor for low voltages. In general if I1 is a fraction of the current Iref, the variation of the current Iref in relation to the threshold voltage Vtl of the circuit of FIG. 2 is lower than the variation of the current Iref in relation to the threshold voltage of the circuit of FIG. 1.

In regard to the variation of the current Iref in relation to the variation of the thickness of the oxide Tox, we have that if we indicate with Tox1 the thickness of the oxide of the transistor ML and Tox2 the thickness of the oxide of the transistor MN, we have for example that if Tox2=4tox1 and making I2=4I1 we have that the variation of the reference current Iref in relation to the variation of the thickness of the oxide is given by

$$\frac{\partial Iref}{\partial Tox} = \frac{\partial I 1}{\partial Tox 1} + \frac{\partial I 2}{\partial Tox 2} = - \frac{2 I 1}{Tox 1} = - \frac{2 Iref}{5 Tox 1}$$

which is lower than the variation Iref/Tox that would be obtained with the known circuits, for example the circuit of FIG. 1.

Another basic circuit in accordance with the invention is shown in FIG. 3. Said apparatus comprises in addition to the circuit branches 1 and 2 of the apparatus of FIG. 2, to which have been added respectively the transistors ML1 and MH1 having the gate terminal connected to the voltages BG1 and BG2, also two more circuit branches 3 and 4; the circuit branches 1-4 are connected in parallel. Said two circuit branches 3 and 4 are formed by two natural transistors M3, M4 and by two resistances R3 and R4 connected to the source terminals of the transistors M3 and M4 and to ground and made in a different manner; for example the resistance R3 is made by means of a region of the N type or N-well and the resistance R4 is made by means of a semiconductor region with a diffusion of N-type or P-type doping. The resistances R3 and R4 have different characteristics seeing that they are made with distinct process phases that make their parameters non correlated. The variations of the fractions 13, 14 of the current Iref caused by the resistances R3 and R4 will undergo different variations and such that the current Iref will have a variation depending on the resistance which will be lower than the known reference current generators, that is when the current Iref is generated by only one of said circuit branches.

FIG. 4 shows a delay circuit in accordance with the invention. Differently from the previous embodiment in which the total magnitude was obtained by summing the partial magnitudes generated by cells placed in parallel, in this case the total magnitude will be obtained by disposing the cells in cascade. The delay T is obtained thus by putting in cascade single delay cells and using similarly the approach explained at the beginning, the single delay cells will be made with circuit elements constituted with elements having process parameters that are not correlated. For one cell capacitors made by means of N-type regions or N-well could be used, for another cell capacitors could be used which are made by means of layers of polysilicon or capacitors made by means of semiconductor regions with diffusion of P or N type doping. For the transistors that instead will give rise to the discharge current here too can be used components with parameters that are not correlated such as transistors for low voltages or transistors for high voltages. Said delay circuit comprises therefore a first part 100 suitable for generating a delay T1 and a second part 200 suitable for generating a second delay T2. The first part 100 comprises a transistor M100 of the low voltage type and a capacitor C1 while the part 200 comprises a transistor M200 of the high voltage type with a capacitor C2; the gate terminals of the transistors M100 and M200 are connected to two bandgap voltages BG100 and BG200.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A basic electronic circuit suitable for generating a magnitude, said circuit having certain structural characteristics and said magnitude undergoing variations in function of the structural characteristics of said circuit, said circuit comprising at least two circuit parts suitable for supplying respective fractions of said magnitude, wherein said at least two circuit parts have different structural characteristics from each other.

2. The circuit according to claim 1, wherein said circuit is a reference current generator that generates a reference current and said at least two circuit parts are generators of fractions of the reference current and are arranged in parallel.

3. The circuit according to claim 2, wherein said two circuit parts comprise respectively a high voltage MOS transistor and a low voltage MOS transistor.

4. The circuit according to claim 2, wherein said reference current generator comprises four fraction generators of the reference current comprising respectively a high voltage MOS transistor, a low voltage MOS transistor, a natural MOS transistor with a resistance formed with an isolated semiconductor region, and a natural MOS transistor with another resistance formed with a semiconductor region with doping diffusion.

5. The circuit according to claim 1, wherein said circuit is a delay chain and said at least two circuit parts are connected in series to generate a delay.

6. The circuit according to claim 1, wherein a first circuit part of said at least two circuit parts includes a high voltage MOS transistor and a capacitor; and a second circuit part of said at least two circuit parts includes a low voltage MOS transistor and another capacitor.

7. A method of manufacturing a basic electronic circuit, the method comprising:
selecting a magnitude to be generated by the circuit;
creating first and second circuit parts suitable for supplying respective fractions of the magnitude, wherein the first and second circuit parts have different structural characteristics from each other.

8. The method of claim 7, wherein the magnitude is a reference current and the first and second circuit parts are generators of fractions of the reference current and are arranged in parallel.

9. The method of claim 8, wherein the first and second circuit parts comprise respectively a high voltage MOS transistor and a low voltage MOS transistor.

10. The method of claim 8, wherein creating the first circuit part comprises creating a high voltage MOS transistor and creating the second circuit part comprises creating a low voltage MOS transistor in parallel with the high voltage MOS transistor, the method further comprising:
creating a third circuit part that includes a natural MOS transistor with a resistance formed with an isolated semiconductor region; and
creating a fourth circuit part that includes a natural MOS transistor with another resistance formed with a semiconductor region with doping diffusion.

11. The method of claim 7, wherein creating the first circuit part includes creating a first delay element and creating the second circuit part includes creating a second delay element connected in series with the first delay element to generate a delay.

12. The method of claim, wherein the first delay element includes a high voltage MOS transistor and a capacitor; and the second delay element includes a low voltage MOS transistor and another capacitor.
